(19) United States
(12) Patent Application Publication
(10) Pub. No.: US 2023/0345838 A1
(43) Pub. Date: Oct. 26, 2023

(54) PIEZOELECTRIC ELEMENT

(71) Applicant: Murata Manufacturing Co., Ltd., Nagaokakyo-shi (JP)

(72) Inventors: Koji OGISO, Nagaokakyo-shi (JP); Yasunari MIWA, Nagaokakyo-shi (JP); Hideki ISHII, Nagaokakyo-shi (JP); Daisuke KURODA, Nagaokakyo-shi (JP)

(21) Appl. No.: 18/345,332

(22) Filed: Jun. 30, 2023

Related U.S. Application Data
(63) Continuation of application No. PCT/JP2021/047266, filed on Dec. 21, 2021.

(30) Foreign Application Priority Data
Jan. 12, 2021 (JP) 2021-002580

(51) Int. Cl. H10N 30/853; C04B 35/491

(52) U.S. Cl. CPC H10N 30/8554; C04B 35/491; C04B 2235/96; C04B 2235/768

(57) ABSTRACT

A piezoelectric element that includes: a piezoelectric ceramic containing, as a main component thereof, a composite oxide having a perovskite crystal structure; a first electrode on a first face of the piezoelectric ceramic; and a second electrode on a second face of the piezoelectric ceramic opposite the first face. The piezoelectric ceramic mainly has a rhombohedral crystal structure. The crystal axis of the piezoelectric ceramic is {100} oriented, and the direction of the {100} orientation is orthogonal to the direction in which the first electrode and the second electrode face each other.

### CROSS REFERENCE TO RELATED APPLICATIONS

The present application is a continuation of International application No. PCT/JP2021/047266, filed Dec. 21, 2021, which claims priority to Japanese Patent Application No. 2021-002580, filed Jan. 12, 2021, the entire contents of each of which are incorporated herein by reference.

### TECHNICAL FIELD

The present invention relates to a piezoelectric element.

### BACKGROUND ART

Piezoelectric elements can convert electrical energy into mechanical energy and convert mechanical energy into electrical energy.

Patent Document 1 discloses: a piezoelectric element including PZT and electrodes, wherein PZT has a perovskite structure having a composition ratio of Zr and Ti at which the perovskite structure is rhombohedral at room temperature, and the [100] direction, the [010] direction, or the [001] direction of the PZT crystal is oriented substantially perpendicular to the planes of the electrodes; and a piezoelectric element including PZT and electrodes, wherein PZT has a perovskite structure having a composition ratio of Zr and Ti at which the perovskite structure is tetragonal at room temperature, wherein the [001] direction of the PZT crystal is oriented substantially perpendicular to the planes of the electrodes. These piezoelectric elements have a higher piezoelectric constant in the electric field direction and better characteristics than piezoelectric elements known in the related art in which the [111] direction is oriented perpendicular to the planes of electrodes, as described in Patent Document 1.

Patent Document 1: Japanese Unexamined Patent Application Publication No. 11-233844

### SUMMARY OF THE INVENTION

However, there is a need to develop piezoelectric elements having a higher piezoelectric constant to improve the characteristics of piezoelectric elements.

The present invention addresses the features described above and aims at providing a piezoelectric element having a high piezoelectric constant.

A piezoelectric element of the present invention includes: a piezoelectric ceramic containing, as a main component thereof, a composite oxide having a perovskite crystal structure; a first electrode on a first face of the piezoelectric ceramic; and a second electrode on a second face of the piezoelectric ceramic opposite the first face, wherein the piezoelectric ceramic mainly has a rhombohedral crystal structure, a crystal axis of the piezoelectric ceramic is {100} oriented, and a direction of the {100} orientation is orthogonal to a direction in which the first electrode and the second electrode face each other.

A piezoelectric element in another aspect of the present invention includes: a piezoelectric ceramic containing, as a main component thereof, a composite oxide having a perovskite crystal structure; a first electrode on a first face of the piezoelectric ceramic; and a second electrode on a second face of the piezoelectric ceramic opposite the first face, wherein a crystal axis of the piezoelectric ceramic is {100} oriented, a direction of the {100} orientation is orthogonal to a direction in which the first electrode and the second electrode face each other, and a full width at half maximum of a composite peak attributed to diffraction from a (002) plane and a (200) plane in an X-ray diffraction pattern viewed from a {100} oriented plane of the piezoelectric ceramic is 0.5° or more.

The piezoelectric element of the present invention has a higher piezoelectric constant and higher piezoelectricity than non-oriented piezoelectric elements and piezoelectric elements in which the crystal axis is oriented in the direction in which a pair of electrodes face each other.

### BRIEF DESCRIPTION OF THE DRAWINGS

FIG. 1 is a schematic cross-sectional view of the structure of a piezoelectric element of the present invention.

FIG. 2(a) illustrates X-ray diffraction patterns viewed from the {100} oriented plane of six piezoelectric ceramics having different compositions, and FIG. 2(b) is an enlarged view of the diffraction peaks at an X-ray diffraction angle around 45°.

FIG. 3 illustrates the relationship between the polarization axis and the orientation direction of the crystal axis of a plate-shaped ceramic, which is a piezoelectric ceramic.

FIG. 4 schematically illustrates the relationship between the electric field direction, the orientation direction and polarization direction of the plate-shaped ceramic, and the vibration direction of a piezoelectric element.

FIG. 5 illustrates the relationship between the angle of the orientation direction and the piezoelectric constant.

FIG. 6 illustrates the relationship between the angle of the orientation direction and the coupling coefficient.

FIG. 7 is a view for describing vibration modes: 31-mode, 32-mode, and t-mode.

### DETAILED DESCRIPTION OF THE PREFERRED EMBODIMENTS

The characteristics of the present invention will be specifically described below by way of embodiments of the present invention.

A piezoelectric element of the present invention includes: a piezoelectric ceramic containing, as a main component, a composite oxide having a perovskite crystal structure; and a first electrode on a first face of the piezoelectric ceramic, and a second electrode on a second face opposite the first face, wherein the piezoelectric ceramic mainly has a rhombohedral crystal structure, the crystal axis of the piezoelectric ceramic is {100} oriented, and the direction of the {100} orientation is orthogonal to the direction in which the first electrode and the second electrode face each other.

In another embodiment, a piezoelectric element of the present invention includes: a piezoelectric ceramic containing, as a main component, a composite oxide having a perovskite crystal structure; and a first electrode on a first face of the piezoelectric ceramic, and a second electrode on a second face opposite the first face, wherein the crystal axis of the piezoelectric ceramic is {100} oriented, the direction of the {100} orientation is orthogonal to the direction in which the first electrode and the second electrode face each other, and the full width at half maximum of a composite peak attributed to diffraction from a (002) plane and a (200) plane in an X-ray diffraction pattern viewed from a {100} oriented plane of the piezoelectric ceramic is 0.5° or more.

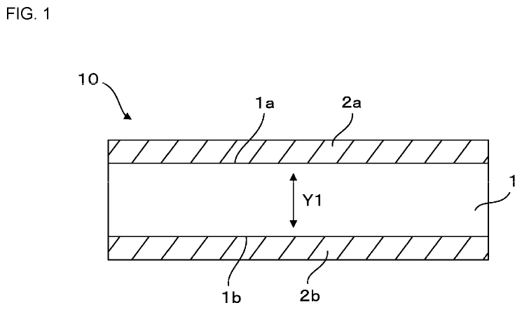

FIG. 1 is a schematic cross-sectional view of the structure of a piezoelectric element 10 of the present invention. The piezoelectric element 10 of the present invention includes: a piezoelectric ceramic 1; and a first electrode 2a on a first face 1a of the piezoelectric ceramic 1, and a second electrode 2b on a second face 1b opposite the first face 1a.

The piezoelectric ceramic 1 contains a composite oxide having a perovskite crystal structure as a main component. The main component means any component accounting for 50% by weight or more of the piezoelectric ceramic 1 among contained components. Examples of the composite oxide having a perovskite crystal structure include PZT (lead zirconate titanate), PNN-PZT (lead nickel niobate (PNN)-lead titanate (PT)-lead zirconate (PZ)), and PMN-PZT (lead magnesium niobate (PMN)-lead titanate (PT)-lead zirconate (PZ).

The crystal axis of the piezoelectric ceramic 1 is {100} oriented, that is, oriented in the [100] direction, the [010] direction, or the [001] direction. The direction of the {100} orientation is a direction orthogonal to the direction (direction denoted by arrow Y1 in FIG. 1) in which the first electrode 2a and the second electrode 2b face each other, that is, a direction parallel to the first face 1a and the second face 1b of the piezoelectric ceramic 1. In the present invention, the “direction orthogonal to the direction in which the first electrode 2a and the second electrode 2b face each other” includes a direction within±10° from the orthogonal direction. When the degree of orientation including the orientation of the [100] axis, the [010] axis, or the [001] axis is 0.30 or more in the Lotgering method, the crystal axis of the piezoelectric ceramic 1 is {100} oriented. The piezoelectric ceramic 1 may have a multilayer structure including two or more layers stacked on top of each other.

The direction of the {100} orientation can be determined as described below. Specifically, the surfaces or cross sections of the main faces, side faces, and end faces of the element are analyzed by the θ-2θ method in an XRD analyzer, and the face that shows the highest value in the Lotgering method corresponds to the orientation direction.

The piezoelectric ceramic 1 mainly has a rhombohedral (R-phase) crystal structure, and the full width at half maximum of the composite peak attributed to diffraction from the (002) plane and the (200) plane in the X-ray diffraction pattern viewed from the {100} oriented plane in X-ray diffraction is 0.5° or more. The expression “the piezoelectric ceramic 1 mainly has a rhombohedral crystal structure” means that at least 50% or more of the piezoelectric ceramic 1 has a rhombohedral crystal structure.

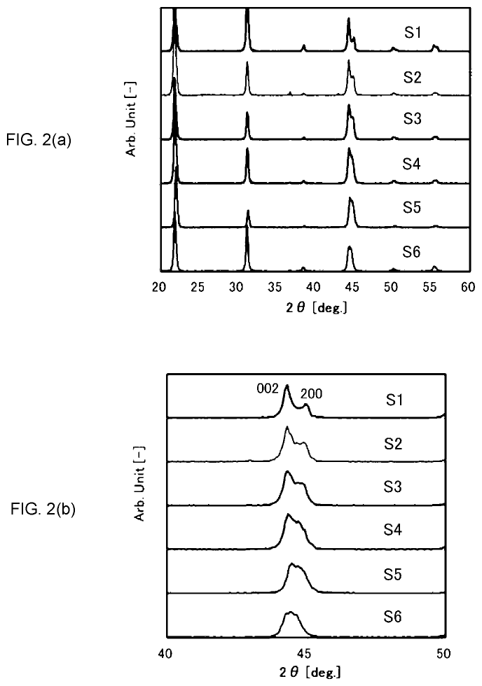

FIG. 2(a) illustrates X-ray diffraction patterns viewed from the {100} oriented planes of six piezoelectric ceramics having different compositions. FIG. 2(b) is an enlarged view of the diffraction peaks at an X-ray diffraction angle around 45°. In FIG. 2(b), the diffraction peaks at an X-ray diffraction angle around 45° are composite peaks attributed to diffraction from the (002) plane and the (200) plane. In FIGS. 2(a) and 2(b), six piezoelectric ceramic samples are referred to as samples S1 to S6 from above. Samples S1 to S6 are polarized samples. For polarized elements, the X-ray diffraction pattern is preferably measured after the polarized elements are depoled by heating the elements to a Curie point or higher.

As illustrated in FIGS. 2(a) and 2(b), the diffraction pattern of sample S1 has two peaks: the diffraction peak of the (002) plane, and the diffraction peak of the (200) plane. The diffraction pattern of sample S6 has a composite peak in which the diffraction peak of the (002) plane overlaps the diffraction peak of the (200) plane. The reason why the diffraction peak of the (002) plane and the diffraction peak of the (200) plane are observed is that the piezoelectric ceramic 1 has a MPB composition, which is a transition region between the R-phase and the T-phase, and microscopically includes regions where the a-axis length of the crystal is different form the c-axis length.

The full width at half maximum of the composite peak attributed to diffraction from the (002) plane and the (200) plane of sample S6 is 0.5° or more. The full width at half maximum of the composite peak attributed to diffraction from the (002) plane and the (200) plane of samples S3 to S5 is also 0.5° or more. The height of the diffraction peak of the (200) plane of sample S2 is higher than half the height of the diffraction peak of the (002) plane, and the full width at half maximum of the composite peak attributed to diffraction from the (002) plane and the (200) plane of sample S2 is 0.5° or more.

The height of the diffraction peak of the (200) plane of sample S1 is lower than half the height of the diffraction peak of the (002) plane. For this, the full width at half maximum of the composite peak attributed to diffraction from the (002) plane and the (200) plane of sample S1 is less than 0.5°. Therefore, the piezoelectric ceramic of sample S1 cannot serve as the piezoelectric ceramic 1 of the piezoelectric element 10 of the present invention.

Having the structure described above, the piezoelectric element 10 of the present invention has high piezoelectricity. The piezoelectric element 10 of the present invention can be used in various piezoelectric devices, such as piezoelectric vibrators, piezoelectric filters, and piezoelectric actuators.

### EXAMPLE

Powders of Pb₃O₄, TiO₂, ZrO₂, NiO, and Nb₂O₅ were provided and weighed so as to obtain a desired composition. The mixed powder was then placed in a pot mill together with water and mixed for 16 hours. Subsequently, the mixture was dried and then calcined at 900° C. The resulting calcined powder was mixed with a binder aqueous solution, and then ground and mixed in a pot mill for 16 hours to obtain a slurry.

The obtained slurry was applied in a sheet form by the doctor blade method, and a magnetic field of 10 T was then applied in a direction parallel to the sheet until the sheet was dried, whereby a ceramic green sheet was produced. The produced ceramic green sheet was cut into pieces having a predetermined size, and the pieces of the ceramic green sheet were then stacked on top of each other such that they were oriented in the same direction. The stacked pieces were press-bonded to each other at a pressure of 100 MPa to produce a green compact.

The produced green compact was degreased by heating in air at 350° C. for 5 hours, and then fired in air at 1050° C. for 2 hours to produce a plate-shaped ceramic, which was a piezoelectric ceramic.

Subsequently, an Ag electrode was formed on each of the main faces, the front face and the back face, of the plate-shaped ceramic by sputtering, and the poling treatment was then carried out at 80° C. and 2 kV/mm for 30 minutes. Finally, the plate-shaped ceramic with the Ag electrodes was cut with a dicer such that the orientation direction was the longitudinal direction to produce a cuboidal piezoelectric element 13 mm long, 3 mm wide, and 0.6 mm thick.

The plate-shaped ceramic of the obtained piezoelectric element contains a composite oxide having a perovskite crystal structure, specifically, PNN-PZT, as a main component.

In this piezoelectric element, the crystal axis of the plate-shaped ceramic, which is a piezoelectric ceramic, is {100} oriented, and the direction of the {100} orientation is orthogonal to the direction in which a pair of electrodes face each other, more specifically, the longitudinal direction of the piezoelectric element. The plate-shaped ceramic mainly has a rhombohedral crystal structure, and the full width at half maximum of the composite peak attributed to diffraction from the (002) plane and the (200) plane in the X-ray diffraction pattern viewed from the {100} oriented plane is 0.5° or more. The X-ray diffraction pattern was obtained by the θ-2θ method using an X-ray diffractometer MiniFlex 2 available from Rigaku Corporation, equipped with a Cu X-ray tube under the conditions of a scan speed of 4°/min, a step width of 0.02°, and a slit width of 1.25°. From the collected data, the Kα2 peaks were stripped by using analysis software Jade 5.0.

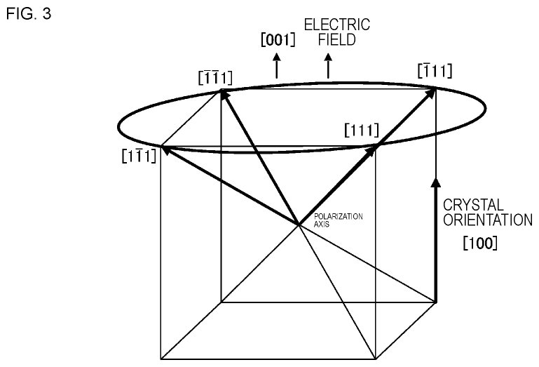

FIG. 3 illustrates the relationship between the polarization axis and the orientation direction of the crystal axis of the plate-shaped ceramic. In FIG. 3, the direction of the polarization axis, which is the direction of spontaneous polarization, is the [111] direction, and the direction of the poling treatment is the same as the direction of electric field application.

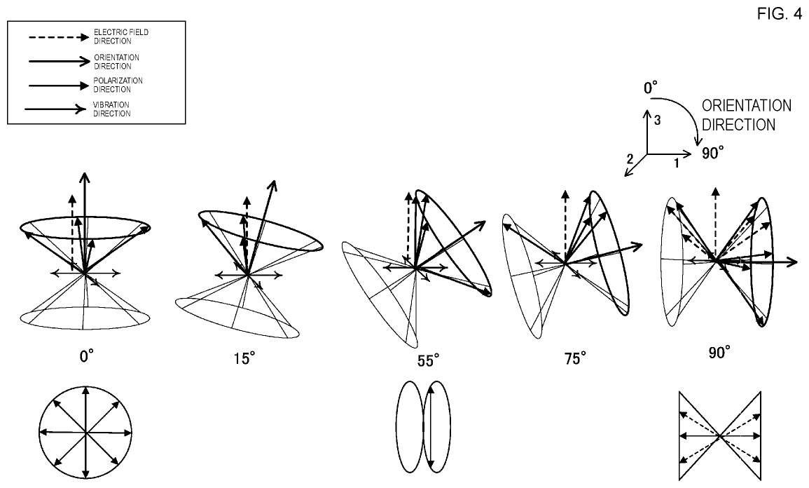

Piezoelectric elements different in the angle of the orientation direction were produced by changing the direction of magnetic field application, and the piezoelectric constant of the produced piezoelectric elements was determined. FIG. 4 schematically illustrates the relationship between the electric field direction, the orientation direction and polarization direction (direction of spontaneous polarization) of the plate-shaped ceramic, and the vibration direction of the piezoelectric element in the case of ideal 100% orientation. In FIG. 4, the relationship between each direction when the orientation direction has an angle of 0°, 15°, 55°, 75°, and 90°. The angle of the orientation direction is the angle to the electric field direction, that is, the direction in which a pair of electrodes face each other. The orientation direction of the piezoelectric element of the present invention has an angle of 90°, and the orientation direction of the piezoelectric element described in Patent Document 1 has an angle of 0°.

FIG. 4 also illustrates the polarization directions viewed in the electric field direction when the orientation direction has an angle of 0°, 55°, and 90°. Referring to FIG. 4, when the orientation direction has an angle of 0°, the polarization directions are distributed in a conical region, and the polarization directions are uniformly distributed in the plane as viewed from above; and when the orientation direction has an angle of 90°, the conical region where the polarization directions can be distributed faces sideways, and the polarization directions are unevenly distributed in the plane and converge in a certain direction as viewed from above.

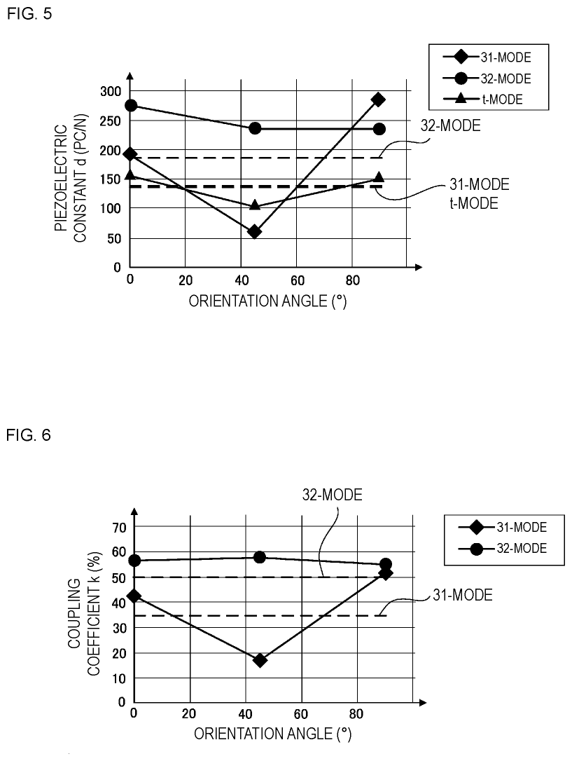

FIG. 5 illustrates the relationship between the angle of the orientation direction and the piezoelectric constant. FIG. 6 illustrates the relationship between the angle of the orientation direction and the coupling coefficient. The coupling coefficient is one of the parameters that express the magnitude of the piezoelectric effect. The larger the coupling coefficient, the higher the piezoelectric effect. In FIG. 5 and FIG. 6, the data indicated by dotted lines are values for non-orientation.

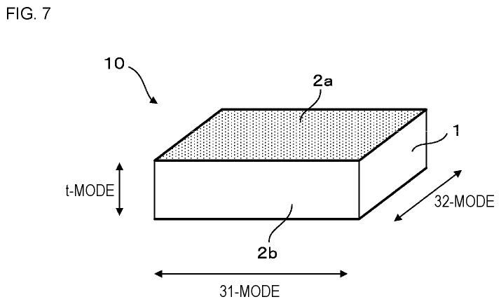

The modes called 31-mode, 32-mode, and t-mode in FIG. 5 and FIG. 6 are vibration modes in different directions in the same sample as illustrated in FIG. 7. As illustrated in FIG. 7, the 31-mode is the vibration mode of the first face, which has the first electrode 2a thereon, and the second face, which has the second electrode 2b thereon, in the longitudinal direction. The orientation direction having an angle of 90° is adjusted so as to coincide with the longitudinal direction of the first face and the second face.

As illustrated in FIG. 5, the piezoelectric constant in the 31-mode is the largest when the orientation direction has an angle of 90°. Specifically, the piezoelectric element 10 of the present invention, where the crystal axis of the piezoelectric ceramic mainly having a rhombohedral crystal structure is {100} oriented, and the direction of the {100} orientation is orthogonal to the direction in which the first electrode 2a and the second electrode 2b face each other, has a higher piezoelectric constant and higher piezoelectricity than non-oriented piezoelectric elements and piezoelectric elements oriented in the direction in which a pair of electrodes face each other, such as the piezoelectric element described in Patent Document 1. This may be because the polarization directions of the piezoelectric ceramic 1 converge in the vibration direction.

When the direction of the {100} orientation is the longitudinal direction of the first face 1a and second face 1b of the piezoelectric ceramic 1 among the directions orthogonal to the direction in which the first electrode 2a and the second electrode 2b face each other, an advanced vibration effect is obtained. Therefore, the direction of the {100} orientation is preferably the longitudinal direction of the first face 1a and second face 1b of the piezoelectric ceramic 1.

In the piezoelectric element described in Patent Document 1, the crystal orientation is controlled by using the crystal growth from the substrate, and the crystal can thus be oriented only in the direction in which a pair of electrodes face each other.

However, the orientation direction of the piezoelectric element 10 of the present invention can be freely controlled because the crystal growth from the substrate is not used. Unlike single crystal, the piezoelectric element 10 of the present invention is relatively easily put to industrially practical use from the viewpoint of composition control and ease in processing. In addition, a piezoelectric element having a multilayer structure can also be produced by stacking ceramic green sheets on top of each other, as described above in Example.

The present invention is not limited to the embodiments described above, and various adaptations and modifications can be made without departing from the scope of the present invention.

### REFERENCE SIGNS LIST

1 Piezoelectric ceramic

1a First face

1b Second face

2a First electrode

2b Second electrode

10 Piezoelectric element

1. A piezoelectric element comprising:
a piezoelectric ceramic containing, as a main component thereof, a composite oxide having a perovskite crystal structure;
a first electrode on a first face of the piezoelectric ceramic; and
a second electrode on a second face of the piezoelectric ceramic opposite the first face,
wherein the piezoelectric ceramic mainly has a rhombohedral crystal structure,
a crystal axis of the piezoelectric ceramic is {100} oriented, and
a direction of the {100} orientation is orthogonal to a direction in which the first electrode and the second electrode face each other.

2. The piezoelectric element according to claim 1, wherein a full width at half maximum of a composite peak attributed to diffraction from a (002) plane and a (200) plane in an X-ray diffraction pattern viewed from a {100} oriented plane of the piezoelectric ceramic is 0.5° or more.

3. The piezoelectric element according to claim 1, wherein the direction of the {100} orientation corresponds to a longitudinal direction of the first face and the second face.

4. The piezoelectric element according to claim 1, wherein the composite oxide is PZT.

5. The piezoelectric element according to claim 1, wherein the composite oxide is PNN-PZT.

6. The piezoelectric element according to claim 1, wherein the composite oxide is PMN-PZT.

7. A piezoelectric element comprising:
a piezoelectric ceramic containing, as a main component thereof, a composite oxide having a perovskite crystal structure;
a first electrode on a first face of the piezoelectric ceramic; and
a second electrode on a second face of the piezoelectric ceramic opposite the first face,
wherein a crystal axis of the piezoelectric ceramic is {100} oriented,
a direction of the {100} orientation is orthogonal to a direction in which the first electrode and the second electrode face each other, and
a full width at half maximum of a composite peak attributed to diffraction from a (002) plane and a (200) plane in an X-ray diffraction pattern viewed from a {100} oriented plane of the piezoelectric ceramic is 0.5° or more.

8. The piezoelectric element according to claim 7, wherein the direction of the {100} orientation corresponds to a longitudinal direction of the first face and the second face.

9. The piezoelectric element according to claim 7, wherein the composite oxide is PZT.

10. The piezoelectric element according to claim 7, wherein the composite oxide is PNN-PZT.

11. The piezoelectric element according to claim 7, wherein the composite oxide is PMN-PZT.
